(19) United States
(12) Patent Application Publication
(10) Pub. No.: US 2021/0020488 A1
(43) Pub. Date: Jan. 21, 2021

(54) WAFER SUPPORT UNIT AND WAFER TREATMENT SYSTEM INCLUDING THE SAME

(71) Applicant: SEMES CO., LTD., Chungcheongnam-do (KR)

(72) Inventors: So Hyung Jiong, Daejeon (KR); Sang-Kee Lee, Chungcheongnam-do (KR)

(21) Appl. No.: 16/924,519

(22) Filed: Jul. 9, 2020

(30) Foreign Application Priority Data
Jul. 15, 2019 (KR) 10-2019-0085259

(51) Int. Cl. H01L 21/683; H01L 21/67; H01J 37/32

(52) U.S. Cl. CPC H01L 21/6833; H01L 21/67069; H01J 37/3244; H01J 2237/2005; H01J 37/32642; H01J 2237/2007; H01J 2237/334; H01J 37/32724

(57) ABSTRACT

Provided are a wafer support unit, in which a dam is installed outside an O-ring to prevent the O-ring from being etched, and a wafer treatment system including the wafer support unit. The wafer treatment system includes: a housing; a shower head introduces a process gas for etching a wafer into the housing; and a support unit includes an electrostatic chuck on which the wafer is mounted, a base supporting the electrostatic chuck, and a focus ring installed on side surfaces of the electrostatic chuck, wherein the support unit includes: a fixing component which fixes the focus ring to the base; a sealing component which is disposed between the focus ring and the base to seal a circumference of a fastening component; and a dam component which is installed outside the sealing component to prevent the sealing component from being etched by the process gas.

### CROSS REFERENCE TO RELATED APPLICATIONS

This application claims the benefit of Korean Patent Application No. 10-2019-0085259, filed on Jul. 15, 2019, in the Korean Intellectual Property Office, the disclosure of which is incorporated herein by reference in its entirety.

### BACKGROUND

### 1. Field

The present disclosure relates to a wafer support unit and a wafer treatment system including the same, and more particularly, to a wafer support unit including a focus ring and a wafer treatment system including the wafer support unit.

### 2. Description of the Related Art

A semiconductor device may be manufactured by forming a predetermined pattern on a wafer. When the predetermined pattern is formed on the wafer, a lot of processes including a depositing process, a lithography process, and an etching process may be continuously performed in equipment used for a semiconductor manufacturing process.

A dry etching process used to manufacture a semiconductor device may be performed in a process chamber. The process chamber includes a focus ring on side surfaces of an electrostatic chuck so that plasma can be generated only around a wafer.

The focus ring may be fastened to a base, which supports the electrostatic chuck, using a clamp and an O-ring. However, the O-ring may be etched during the dry etching process due to a fastening method of the clamp.

### SUMMARY

Aspects of the present disclosure provide a wafer support unit in which a dam is installed outside an O-ring to prevent the O-ring from being etched.

Aspects of the present disclosure also provide a wafer treatment system including a wafer support unit in which a dam is installed outside an O-ring to prevent the O-ring from being etched.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a wafer treatment system including: a housing; a shower head which is installed on an upper side inside the housing and introduces a process gas for etching a wafer into the housing; and a support unit which is installed on a lower side inside the housing and includes an electrostatic chuck on which the wafer is mounted, a base supporting the electrostatic chuck, and a focus ring installed on side surfaces of the electrostatic chuck, wherein the support unit includes: a fixing component which fixes the focus ring to the base; a sealing component which seals a circumference of a fastening component for fastening the focus ring and the base to each other; and a dam component which is installed outside the sealing component to prevent the sealing component from being etched by the process gas.

The dam component may be joined to at least one of the base and the focus ring and then installed outside the sealing component.

The dam component may be made of the same material as the base or made of an insulating material.

The fixing component may be a clamp, the sealing component may be an O-ring, and the dam component may be installed to surround the O-ring.

The support unit may further include at least one of a heater which is installed inside the base and heats the focus ring and a gas supply unit which supplies a gas for transferring heat generated by the heater to a bottom surface of the focus ring.

The gas supply unit may supply helium gas as the gas.

The gas supply unit may include: a gas supply source which provides the gas; and a gas supply line which is installed inside the base and connects the gas supply source and the focus ring, wherein the dam component may be installed to surround an end of the gas supply line, which is adjacent to the focus ring, and the sealing component.

The heater may be installed adjacent to the focus ring, installed adjacent to a cooling component installed inside the base, or installed adjacent to both the focus ring and the cooling component.

The dam component may be installed when the focus ring is fixed to the base using the fixing component and the sealing component.

The focus ring may be fixed to the base using the fixing component and the sealing component when a gas for controlling a temperature of the focus ring is supplied.

The sealing component may seal a circumference of a side of the fastening component located between the focus ring and the base.

When the heater is installed adjacent to the focus ring, the heater may be installed to contact a bottom part of the focus ring.

The gas supply unit may supply the gas to the focus ring through the gas supply line, and the gas supply line may be formed to penetrate the heater when the heater is installed to contact the entire bottom part of the focus ring and may be formed not to penetrate the heater when the heater is installed to partially contact the bottom part of the focus ring.

According to another aspect of the present disclosure, there is provided a wafer treatment system including: a housing; a shower head which is installed on an upper side inside the housing and introduces a process gas for etching a wafer into the housing; and a support unit which is installed on a lower side inside the housing and includes an electrostatic chuck on which the wafer is mounted, a base supporting the electrostatic chuck, and a focus ring installed on side surfaces of the electrostatic chuck, wherein the support unit includes: a fixing component which fixes the focus ring to the base; a sealing component which is disposed between the focus ring and the base to seal a circumference of a fastening component for fastening the fixing component; and a dam component which is installed outside the sealing component to prevent the sealing component from being etched by the process gas, wherein the dam component is installed to surround the sealing component when a gas for controlling a temperature of the focus ring is supplied and when the focus ring is fixed to the base using the fixing component and the sealing component.

According to another aspect of the present disclosure, there is provided a wafer support unit installed inside a housing that provides a space in which a wafer is treated and including: an electrostatic chuck on which the wafer is mounted; a base which supports the electrostatic chuck; a focus ring which is installed on side surfaces of the electrostatic chuck; a fixing component which fixes the focus ring to the base; a sealing component which seals a circumference of a fastening component for fastening the focus ring and the base to each other; and a dam component which is installed outside the sealing component to prevent the sealing component from being etched by a process gas.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view schematically illustrating the structure of a wafer treatment system including a support unit according to an embodiment of the present disclosure;

FIG. 2 is a partial enlarged view of a support unit according to an embodiment of the present disclosure;

FIG. 3 is an example view illustrating the installation form of dam components constituting the support unit according to the embodiment of the present disclosure;

FIG. 4 is an example view illustrating the installation form of the dam components constituting the support unit according to the embodiment of the present disclosure;

FIG. 5 is an example view illustrating the installation form of the dam components constituting the support unit according to the embodiment of the present disclosure;

FIG. 6 is a cross-sectional view schematically illustrating the structure of a wafer treatment system including a support unit according to an embodiment of the present disclosure;

FIG. 7 is a partial enlarged view of a support unit according to an embodiment of the present disclosure;

FIG. 8 is an example view illustrating the installation form of a heater constituting the support unit according to the embodiment of the present disclosure;

FIG. 9 is an example view illustrating the installation form of the heater constituting the support unit according to the embodiment of the present disclosure;

FIG. 10 is a cross-sectional view schematically illustrating the structure of a wafer treatment system according to an embodiment of the present disclosure; and

FIG. 11 is a cross-sectional view schematically illustrating the structure of a wafer treatment system according to an embodiment.

### DETAILED DESCRIPTION

Hereinafter, exemplary embodiments of the present disclosure will be described in greater detail with reference to the attached drawings. Advantages and features of the present disclosure and methods of accomplishing the same may be understood more readily by reference to the following detailed description of exemplary embodiments and the accompanying drawings. The present disclosure may, however, be embodied in many different forms and should not be construed as being limited to the embodiments set forth herein. Rather, these embodiments are provided so that this disclosure will be thorough and complete and will fully convey the concept of the invention to those skilled in the art, and the present disclosure will only be defined by the appended claims. Like reference numerals refer to like elements throughout the specification.

It will be understood that when an element or layer is referred to as being “on” another element or layer, the element or layer can be directly on another element or layer or intervening elements or layers. In contrast, when an element is referred to as being “directly on” another element or layer, there are no intervening elements or layers present.

Spatially relative terms, such as “below,” “beneath,” “lower,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” or “beneath” can encompass both an orientation of above and below. The device may be otherwise oriented and the spatially relative descriptors used herein interpreted accordingly.

It will be understood that, although the terms first, second, third, etc., may be used herein to describe various elements, components and/or sections, these elements, components and/or sections should not be limited by these terms. These terms are only used to distinguish one element, component or section from another element, component or section.

Thus, a first element, component or section discussed below could be termed a second element, component or section without departing from the teachings of the present disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described in detail with reference to the attached drawings. In the following description with reference to the attached drawings, like or corresponding elements will be indicated by like reference numerals, and a redundant description thereof will be omitted.

The present disclosure relates to a wafer support unit, in which a dam is installed outside an O-ring to prevent the O-ring from being etched when a focus ring is fastened to a base by using a clamp and the O-ring, and a wafer treatment system including the wafer support unit. The present disclosure will hereinafter be described in detail with reference to the attached drawings and the like.

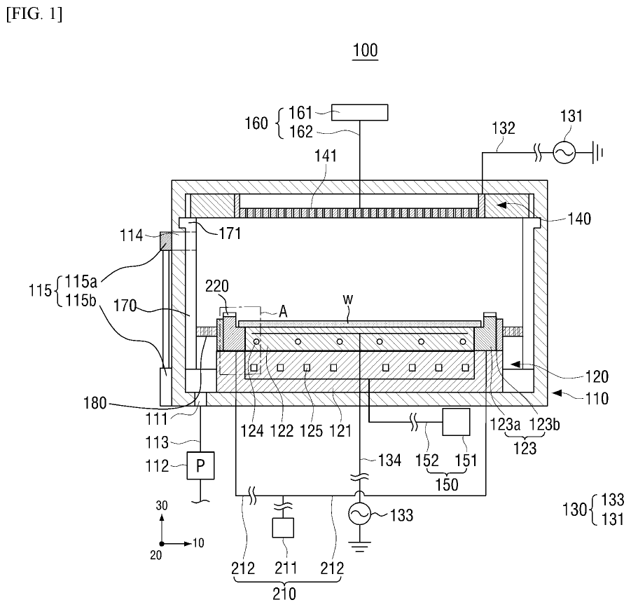

FIG. 1 is a cross-sectional view schematically illustrating the structure of a wafer treatment system 100 including a support unit 120 according to an embodiment of the present disclosure.

Referring to FIG. 1, the wafer treatment system 100 may include a housing 110, the support unit 120, a plasma generation unit 130, a shower head 140, a first gas supply unit 150, a second gas supply unit 160, a liner (or wall liner) 170, and a baffle unit 180.

The wafer treatment system 100 is a system for treating a wafer W using a dry etching process. The wafer treatment system 100 may treat the wafer W using, for example, a plasma process.

The housing 110 provides a space in which a plasma process is performed. The housing 110 may include an exhaust hole 111 at its bottom.

The exhaust hole 111 may be connected to an exhaust line 113 on which a pump 112 is mounted. The exhaust hole 111 may discharge reaction byproducts generated in a plasma process and gas remaining inside the housing 110 to the outside of the housing 110 through the exhaust line 113. In this case, the space inside the housing 110 may be depressurized to a predetermined pressure level.

The housing 110 may have an opening 114 formed in its sidewall. The opening 114 may function as a passage through which the wafer W is inserted into and removed from the housing 110. The opening 114 may be opened and closed by a door assembly 115.

The door assembly 115 may include an outer door 115a and a door driver 115b.

The outer door 115a is provided on an outer wall of the housing 110. The outer door 115a may be moved up and down (i.e., in a third direction 30) by the door driver 115b.

The door driver 115b may include a pneumatic cylinder, a motor, etc.

The support unit 120 is installed in a lower area of the inside of the housing 110. The support unit 120 may support the wafer W using electrostatic force. However, the current embodiment is not limited thereto. The support unit 120 may also support the wafer W using various methods such as mechanical clamping, vacuum, and the like.

When the support unit 120 supports the wafer W using electrostatic force, it may include a base 121 and an electrostatic chuck 122.

The electrostatic chuck 122 supports the wafer W mounted thereon by using electrostatic force. The electrostatic chuck 122 may be made of a ceramic material and coupled to the base 121 such that it is fixed on the base 121.

The electrostatic chuck 122 may be installed to be movable up and down (i.e., in the third direction 30) inside the housing 110 by using a driving component (not illustrated). When the electrostatic chuck 122 is formed to be movable up and down, it may be possible to position the wafer W in an area showing a more uniform plasma distribution.

A ring assembly 123 is provided to cover the rim of the electrostatic chuck 122. The ring assembly 123 may be provided in a ring shape and configured to support an edge zone of the wafer W.

The ring assembly 123 may include a focus ring 123a and an insulating ring 123b.

The focus ring 123a is formed inside the insulating ring 123b and surrounds the electrostatic chuck 122. The focus ring 123a may be made of a silicon material and may focus plasma on the wafer W.

The focus ring 123a may be fastened to the base 121 using a clamp and an O-ring. However, when the focus ring 123a is fixed to the base 121 as described above, the O-ring is likely to be etched during a plasma process.

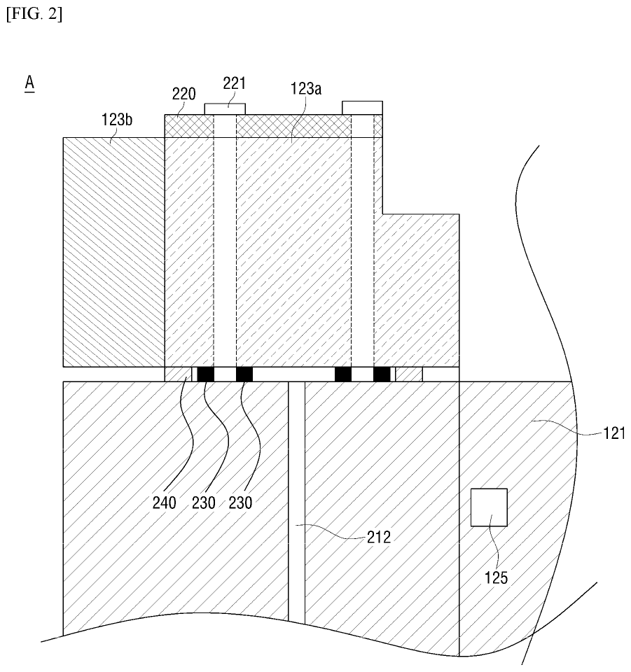

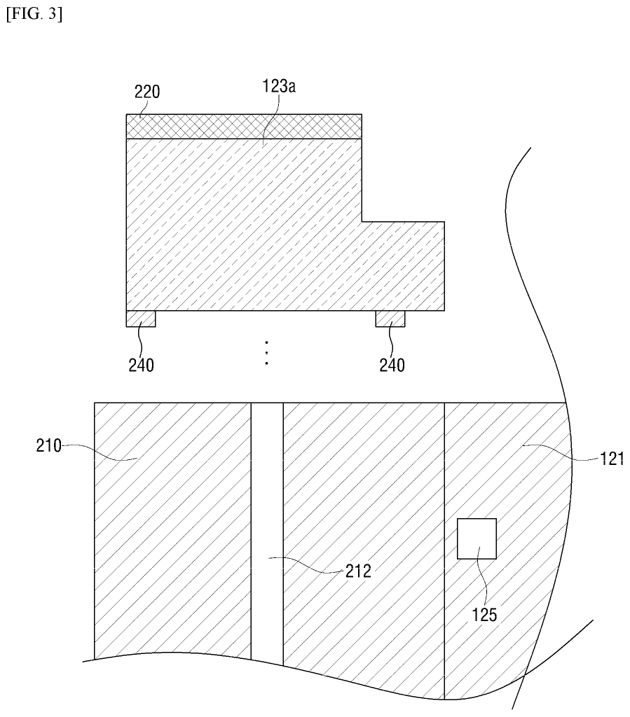

In the current embodiment, a dam may be installed outside the O-ring in order to prevent the O-ring from being etched. This will be described in more detail later with reference to FIGS. 2 and 3.

The insulating ring 123b is formed outside the focus ring 123a and surrounds the focus ring 123a. The insulating ring 123b may be made of a quartz material.

The ring assembly 123 may further include an edge ring formed in close contact with the rim of the focus ring 123a. The edge ring may be formed to prevent side surfaces of the electrostatic chuck 122 from being damaged by plasma.

The first gas supply unit 150 supplies a gas to remove foreign substances remaining on the ring assembly 123 or an edge portion of the electrostatic chuck 122. The first gas supply unit 150 may include a first gas supply source 151 and a first gas supply line 152.

The first gas supply source 151 may supply nitrogen (N2) gas as a gas for removing foreign substances. However, the current embodiment is not limited thereto. The first gas supply source 151 may also supply other gases or cleansing agents.

The first gas supply line 152 is provided between the electrostatic chuck 122 and the ring assembly 123. The first gas supply line 152 may be connected, for example, between the electrostatic chuck 122 and the focus ring 123a.

However, the current embodiment is not limited thereto. The first gas supply line 152 may also be provided inside the focus ring 123a and bent to be connected between the electrostatic chuck 122 and the focus ring 123a.

A heating component 124 and a cooling component 125 are provided to maintain a process temperature of the wafer W while an etching process is performed inside the housing 110. To this end, the heating component 124 may be provided as hot wires, and the cooling component 125 may be provided as cooling lines through which a refrigerant flows.

The heating component 124 and the cooling component 125 may be installed inside the support unit 120 to maintain the process temperature of the wafer W. For example, the heating ember 124 may be installed inside the electrostatic chuck 122, and the cooling component 125 may be installed inside the base 121.

The plasma generation unit 130 generates plasma from a gas remaining in a discharge space. Here, the discharge space refers to a space located above the support unit 120 in the internal space of the housing 110.

The plasma generation unit 130 may generate plasma in the discharge space inside the housing 110 by using a capacitively coupled plasma (CCP) source. In this case, the plasma generation unit 130 may use the shower head 140 as an upper electrode and the electrostatic chuck 122 as a lower electrode.

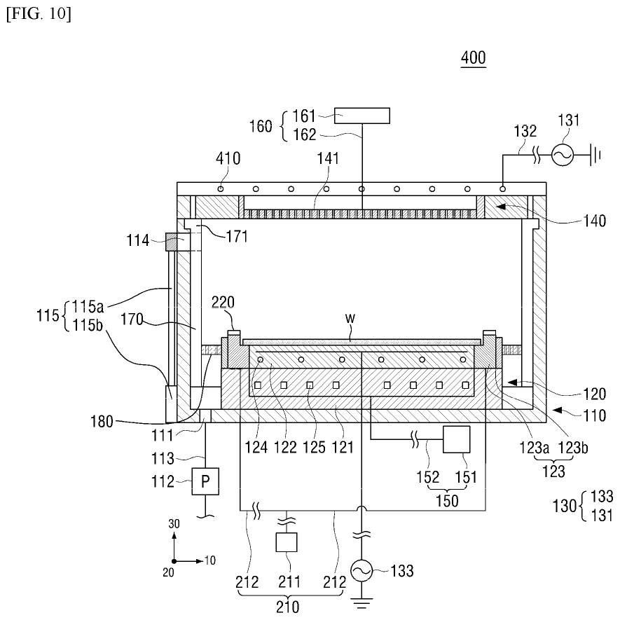

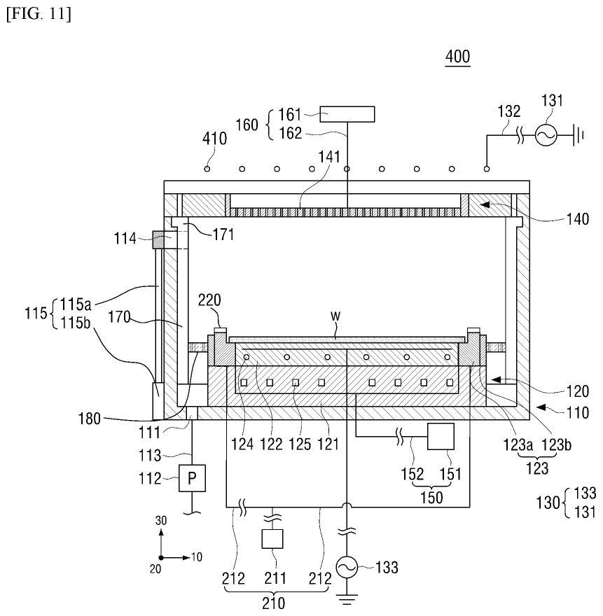

However, the current embodiment is not limited thereto. The plasma generation unit 130 may also generate plasma in the discharge space inside the housing 110 by using an inductively coupled plasma (ICP) source. In this case, the plasma generation unit 130 may use an antenna 410, which is installed in an upper part of the housing 110 as illustrated in FIGS. 10 and 11, as an upper electrode and the electrostatic chuck 122 as a lower electrode.

The structure of a wafer treatment system 400 when the plasma generation unit 130 uses the ICP source will be described later with reference to FIGS. 10 and 11.

The plasma generation unit 130 may include an upper electrode, a lower electrode, an upper power source 131, and a lower power source 132.

As described above, when the plasma generation unit 130 uses the CCP source, the shower head 140 may function as the upper electrode, and the electrostatic chuck 122 may function as the lower electrode.

The shower head 140 functioning as the upper electrode and the electrostatic chuck 122 functioning as the lower electrode may be installed inside the housing 110 to face each other in a vertical direction. The shower head 140 may include a plurality of gas feeding holes 141 to spray gas into the housing 110 and may have a diameter greater than that of the electrostatic chuck 122.

The shower head 140 may be made of a silicon material or a metal material.

The upper power source 131 applies power to the upper electrode, that is, the shower head 140. The upper power source 131 may be provided to control plasma characteristics. The upper power source 131 may be provided to control, for example, ion bombardment energy.

Although only one upper power source 131 is illustrated in FIG. 1, a plurality of upper power sources 131 may also be provided in the current embodiment. When a plurality of upper power sources 131 are provided, the wafer treatment system 100 may further include a first matching network (not illustrated) electrically connected to the upper power sources 131.

The first matching network may match frequency powers of different magnitudes received respectively from the upper power sources 131 and apply them to the shower head 140.

A first impedance matching circuit (not illustrated) for impedance matching may be provided on a first transmission line 132 connecting the upper power source 131 and the shower head 140.

The first impedance matching circuit may act as a lossless passive circuit to transfer electrical energy effectively (i.e., to the maximum) from the upper power source 131 to the shower head 140.

The lower power source 133 applies power to the lower electrode, that is, the electrostatic chuck 122. The lower power source 133 may serve as a plasma source for generating plasma or may control plasma characteristics together with the upper power source 131.

Although only one lower power source 133 is illustrated in FIG. 1, a plurality of lower power sources 133 may also be provided in the current embodiment, like the upper power source 131. When a plurality of lower power sources 133 are provided, a second matching network (not illustrated) electrically connected to the lower power sources 133 may be further included.

The second matching network may match frequency powers of different magnitudes received respectively from the lower power sources 133 and apply them to the electrostatic chuck 122.

A second impedance matching circuit (not illustrated) for impedance matching may be provided on a second transmission line 134 connecting the lower power source 133 and the electrostatic chuck 122.

The second impedance matching circuit may act as a lossless passive circuit to transfer electrical energy effectively (i.e., to the maximum) from the lower power source 133 to the electrostatic chuck 122.

The second gas supply unit 160 supplies a process gas into the housing 110 through the shower head 140. The second gas supply unit 160 may include a second gas supply source 161 and a second gas supply line 162.

The second gas supply source 161 supplies an etching gas used to treat the wafer W as the process gas. The second gas supply source 161 may supply a gas containing a fluorine component as the etching gas. For example, the second gas supply source 161 may supply a gas such as SF6 or CF4 as the etching gas.

One second gas supply source 161 may be provided to supply the etching gas to the shower head 140. However, the current embodiment is not limited thereto. A plurality of second gas supply sources 161 may also be provided to supply the process gas to the shower head 140.

The second gas supply line 162 connects the second gas supply source 161 and the shower head 140. The second gas supply line 162 transfers the process gas supplied from the second gas supply source 161 to the shower head 140, so that the etching gas can be introduced into the housing 110.

When the shower head 140 is divided into a center zone, a middle zone, and an edge zone, the second gas supply unit 160 may further include a gas distributor (not illustrated) and a gas distribution line (not illustrated) to supply the process gas to each zone of the shower head 140.

The gas distributor distributes the process gas supplied from the second gas supply source 161 to each zone of the shower head 140. The gas distributor may be connected to the second gas supply source 161 through the second gas supply line 162.

The gas distribution line connects the gas distributor and each zone of the shower head 140. The gas distribution line may transfer the process gas distributed by the gas distributor to each zone of the shower head 140.

The second gas supply unit 160 may further include a second gas supply source (not illustrated) for supplying a deposition gas.

The second gas supply source supplies the deposition gas to the shower head 140 so as to protect side surfaces of a wafer pattern to enable anisotropic etching. The second gas supply source may supply a gas such as C4F8 or C2F4 as the deposition gas.

The liner 170 is designed to protect an inner surface of the housing 110 from arc discharge generated when the process gas is excited, impurities generated during a wafer treatment process, and the like. The liner 170 may be provided inside the housing 110 and shaped like a cylinder having open upper and lower ends.

The liner 170 may be provided adjacent to inner walls of the housing 110. The liner 170 may include a support ring 171 at its upper end. The support ring 171 may protrude outward (i.e., in a first direction 10) from the upper end of the liner 170 and may be disposed in the upper part of the housing 110 to support the liner 170.

The baffle unit 180 discharges process byproducts of plasma, unreacted gases, and the like. The baffle unit 180 may be installed between the inner walls of the housing 110 and the support unit 120.

The baffle unit 180 may be provided in an annular ring shape and may include a plurality of through holes 181 penetrating the baffle unit 180 in the vertical direction (i.e., the third direction 30). The baffle unit 180 may control the flow of the process gas according to the number and shape of the through holes 181.

Next, the support unit 120 having a dam component to prevent etching of a sealing component will be described.

FIG. 2 is a partial enlarged view of a support unit 120 according to an embodiment of the present disclosure. The following description will be given with reference to FIGS. 1 and 2.

Referring to FIG. 2, the support unit 120 may include a third gas supply unit 210, a fixing component 220, sealing components 230, and dam components 240.

The support unit 120 may use a heat transfer gas to control the temperature of the focus ring 123a. In the current embodiment, helium gas may be used as the heat transfer gas.

The helium gas may be supplied to the focus ring 123a through the third gas supply unit 210. The third gas supply unit 210 may include a third gas supply source 211 and a third gas supply line 212.

The third gas supply source 211 supplies the helium gas to the focus ring 123a through the third gas supply line 212. The third gas supply source 211 may be installed outside the housing 110.

The third gas supply line 212 transfers the helium gas from the third gas supply source 211 to the focus ring 123a. To this end, the third gas supply line 212 may be configured to connect the third gas supply source 211 and the focus ring 123a.

When the helium gas is used as the heat transfer gas, the focus ring 123a may be fixed to the base 121 by the fixing component 220 and the sealing components 230.

The fixing component 220 fixes the focus ring 123a to the base 121. In the current embodiment, a clamp may be used as the fixing component 220.

When the base 121 and the focus ring 123a are fastened to each other using a clamp, circumferences of fastening components 221 such as bolts, in particular, the circumferences of the fastening components 221 located between the base 121 and the focus ring 123a may be sealed using the sealing components 230. In the current embodiment, O-rings may be used as the sealing components 230.

The dam components 240 are step sealing dams and designed to prevent the sealing components 230 from being etched during a plasma process. To this end, the dam components 240 may be installed outside the sealing components 230.

The sealing components 230 may be etched during the plasma process due to the fastening method of the fixing component 220. Accordingly, the helium gas may leak out of the support unit 120. In the current embodiment, the dam components 240 may be installed outside the sealing components 230 to prevent the sealing components 230 from being etched and to prevent the helium gas from leaking out of the support unit 120.

When the dam components 240 are installed outside the sealing components 230, they may be formed to surround the sealing components 230 between the base 121 and the focus ring 123a. The dam components 240 may be joined to the focus ring 123a as illustrated in FIG. 3 and then installed between the base 121 and the focus ring 123a when the base 121 and the focus ring 123a are fastened to each other. FIG. 3 is an example view illustrating the installation form of the dam components 240 constituting the support unit 120 according to the embodiment of the present disclosure.

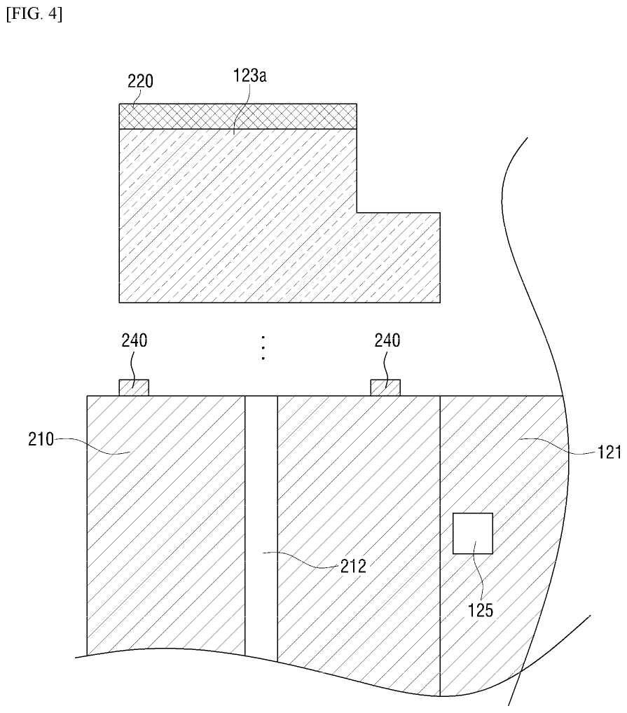

However, the current embodiment is not limited thereto. The dam components 240 may also be joined to the base 121 as illustrated in FIG. 4 and then installed between the base 121 and the focus ring 123a when the base 121 and the focus ring 123a are fastened to each other. FIG. 4 is an example view illustrating the installation form of the dam components 240 constituting the support unit 120 according to the embodiment of the present disclosure.

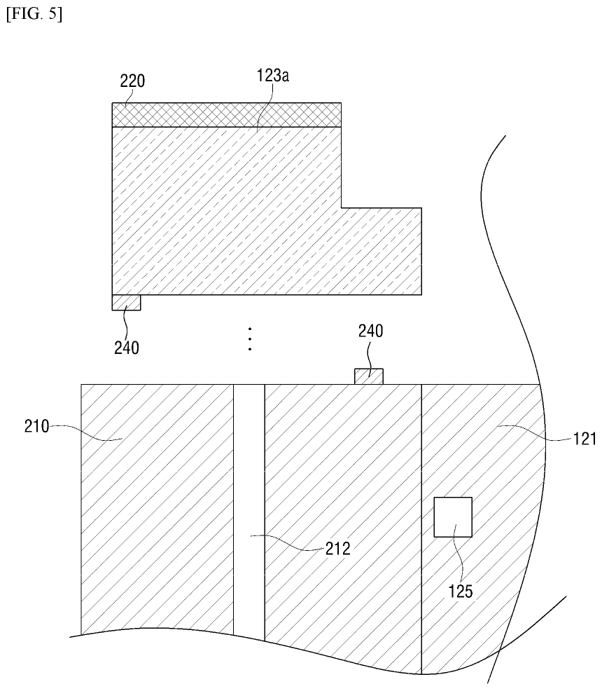

Alternatively, one of the dam components 240 may be joined to the focus ring 123a, and the other dam component 240 may be joined to the base 121 as illustrated in FIG. 5. In this state, the dam components 240 may be installed between the base 121 and the focus ring 123a when the base 121 and the focus ring 123a are fastened to each other. FIG. 5 is an example view illustrating the installation form of the dam components 240 constituting the support unit 120 according to the embodiment of the present disclosure.

The dam components 240 may be made of the same material as the base 121. The dam components 240 may be made of, for example, an insulating material.

The focus ring 123a may be formed in a ‘ ’ shape to partially cover side and bottom surfaces of the wafer W. The focus ring 123a thus formed may affect the temperature of the wafer W.

In the current embodiment, the support unit 120 may independently control the temperature of the focus ring 123a to maximize process efficiency. This will now be described.

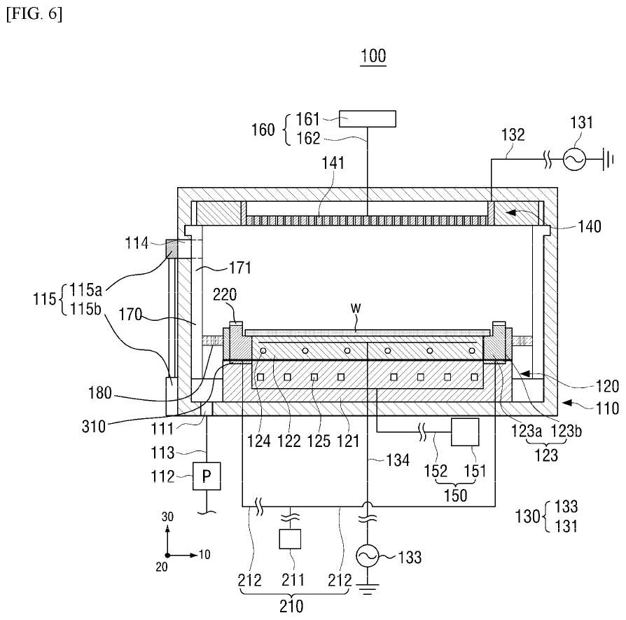

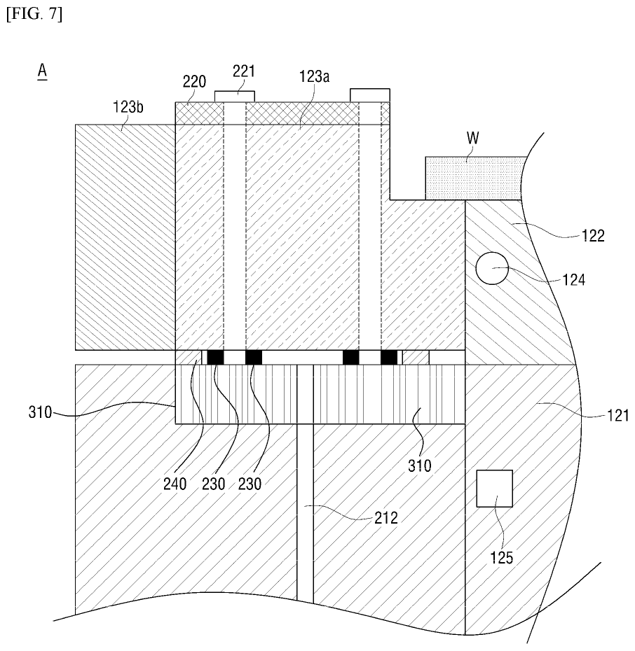

FIG. 6 is a cross-sectional view schematically illustrating the structure of a wafer treatment system 100 including a support unit 120 according to an embodiment of the present disclosure. FIG. 7 is a partial enlarged view of a support unit 120 according to an embodiment of the present disclosure. The following description will be given with reference to FIGS. 6 and 7.

Referring to FIG. 7, the support unit 120 may further include a heater 310.

Since a focus ring 123a can affect the temperature of a wafer W due to its positional characteristics, it is closely related to process efficiency.

The temperature of the focus ring 123a may be controlled using a cooling line of an electrostatic chuck 122 and a silicone pad. However, this structure makes management difficult due to limitations of the silicone pad in heat resistance and the design without an independent temperature control section.

In the current embodiment, the temperature of the focus ring 123a may be independently controlled using a heat transfer gas (e.g., helium gas) and the heater 310.

The heater 310 is for heating the focus ring 123a. The heater 310 may be installed inside a base 121 and adjacent to the focus ring 123a.

In the current embodiment, the focus ring 123a may be controlled to always maintain a constant temperature by heating the focus ring 123a using the heater 310 and supplying the helium gas to a bottom part of the focus ring 123a through a third gas supply line 212. Then, since the focus ring 123a does not affect the temperature change of the wafer W, process efficiency can be improved.

When the heater 310 is installed inside the base 121 and adjacent to the focus ring 123a, it may be installed to contact the entire bottom part of the focus ring 123a. In this case, the third gas supply line 212 may be formed to penetrate the heater 310.

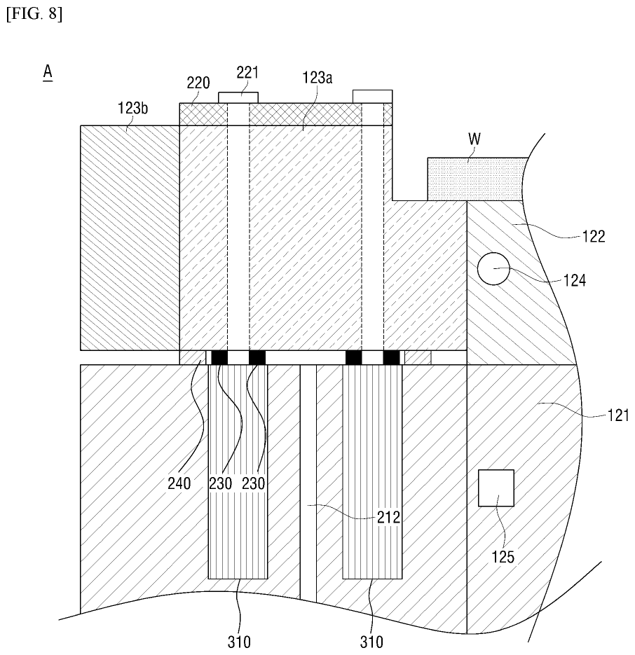

However, the current embodiment is not limited thereto. The heater 310 may also be installed to partially contact the bottom part of the focus ring 123a as illustrated in FIG. 8. In this case, at least one heater 310 may be installed, and the third gas supply line 212 may not penetrate the heater 310. FIG. 8 is an example view illustrating the installation form of the heater 310 constituting the support unit 120 according to the embodiment of the present disclosure.

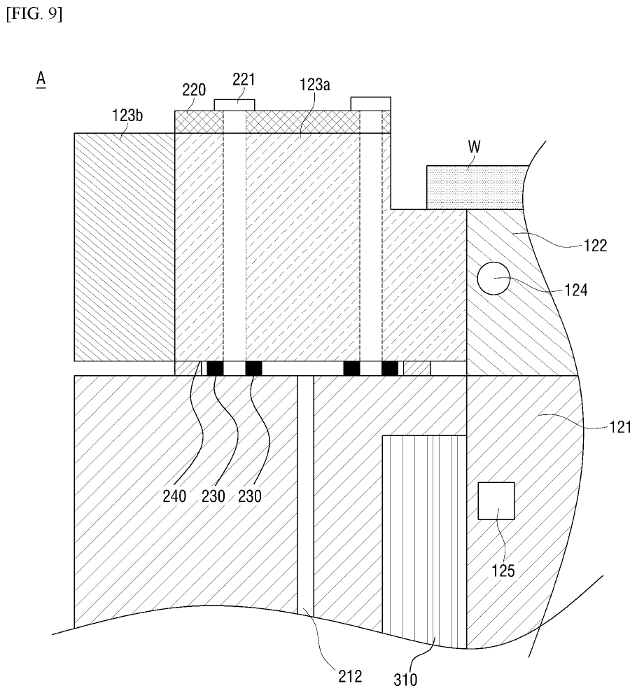

The heater 310 may also be installed adjacent to a cooling component 125 as illustrated in FIG. 9 in order to prevent the temperature of the focus ring 123a from being lowered by the cooling component 125. FIG. 9 is an example view illustrating the installation form of the heater 310 constituting the support unit 120 according to the embodiment of the present disclosure.

When the heater 310 is installed adjacent to the cooling component 125, it may be installed adjacent to the focus ring 123a. However, the current embodiment is not limited thereto. The heater 310 may also be installed not adjacent to the focus ring 123a.

Although not illustrated in FIGS. 6 and 7, the helium gas may be discharged out of a housing 110 through a separate discharge line (not illustrated).

Until now, the structure of the support unit 120 which can prevent the sealing components 230 for sealing the fastening components 221 from being etched when the base 121 and the focus ring 123a are fastened to each other and can independently control the temperature of the focus ring 123a has been described with reference to FIGS. 2 through 9.

According to the current embodiment, the above structure can prevent the focus ring 123a from being displaced or lifted from the base 121 even if the focus ring 123a is fixed to the base 121 using the fixing component 220.

In addition, the sealing components 230 can be prevented from being etched during a plasma process, thereby extending the life of the sealing components 230. Also, the time required to perform a cleaning process, that is, mean time between cleaning (MTBC) can be improved, and process efficiency can also be improved.

Next, the structure of a wafer treatment system 400 when a plasma generation unit 130 uses an ICP source will be described.

FIG. 10 is a cross-sectional view schematically illustrating the structure of a wafer treatment system 400 according to an embodiment of the present disclosure. The following description will be given with reference to FIG. 10.

Referring to FIG. 10, the wafer treatment system 500 may include a housing 110, a support unit 120, a plasma generation unit 130, a shower head 140, a first gas supply unit 150, a second gas supply unit 160, a liner 170, and a baffle unit 180.

The housing 110, the support unit 120, the shower head 140, the first gas supply unit 150, the second gas supply unit 160, the liner 170, and the baffle unit 180 have already been described above with reference to FIG. 1, and thus a detailed description thereof will be omitted.

In addition, the features and elements of the support unit 120 described above with reference to FIGS. 2 through 9 may be applied the same to the wafer treatment system 400 of FIG. 10.

Therefore, only differences between the wafer treatment system 400 of FIG. 10 and the wafer treatment system 100 of FIG. 1 will be described below.

When the plasma generation unit 130 uses an ICP source, an antenna 410 may be used as an upper electrode, and an electrostatic chuck 122 may be used as a lower electrode. Here, an upper power source 131 may apply power to the antenna 410.

The antenna 410 may function as the upper electrode and may be installed in an upper part of the housing 110.

The antenna 410 is equipped with a coil provided to form a closed loop. The antenna 410 generates a magnetic field and an electric field inside the housing 110 based on power supplied from an upper power source 131 so as to excite gas, which is introduced into the housing 110 through the shower head 140, into plasma.

The antenna 410 may be equipped with a planar spiral coil. However, the current embodiment is not limited thereto. The structure or size of the coil can be variously changed by those of ordinary skill in the art.

Alternatively, the antenna 410 may be installed outside the housing 110 and separately from the housing 110. For example, the antenna 410 may be installed above the upper part of the housing 110 as illustrated in FIG. 11. FIG. 11 is a cross-sectional view schematically illustrating the structure of a wafer treatment system according to an embodiment.

While the present disclosure has been particularly shown and described with reference to exemplary embodiments thereof, it will be understood by those of ordinary skill in the art that various changes in form and detail may be made therein without departing from the spirit and scope of the present disclosure as defined by the following claims. The exemplary embodiments should be considered in a descriptive sense only and not for purposes of limitation.

What is claimed is:

1. A wafer treatment system comprising:
a housing;
a shower head which is installed on an upper side inside the housing and introduces a process gas for etching a wafer into the housing; and
a support unit which is installed on a lower side inside the housing and comprises an electrostatic chuck on which the wafer is mounted, a base supporting the electrostatic chuck, and a focus ring installed on side surfaces of the electrostatic chuck,
wherein the support unit comprises:
a fixing component which fixes the focus ring to the base;
a sealing component which seals a circumference of a fastening component for fastening the focus ring and the base to each other; and
a dam component which is installed outside the sealing component to prevent the sealing component from being etched by the process gas.

2. The system of claim 1, wherein the dam component is joined to at least one of the base and the focus ring and then installed outside the sealing component.

3. The system of claim 1, wherein the dam component is made of the same material as the base or made of an insulating material.

4. The system of claim 1, wherein the fixing component is a clamp, the sealing component is an O-ring, and the dam component is installed to surround the O-ring.

5. The system of claim 1, wherein the support unit further comprises at least one of a heater which is installed inside the base and heats the focus ring and a gas supply unit which supplies a gas for transferring heat generated by the heater to a bottom surface of the focus ring.

6. The system of claim 5, wherein the gas supply unit supplies helium gas as the gas.

7. The system of claim 5, wherein the gas supply unit comprises:
a gas supply source which provides the gas; and
a gas supply line which is installed inside the base and connects the gas supply source and the focus ring,
wherein the dam component is installed to surround an end of the gas supply line, which is adjacent to the focus ring, and the sealing component.

8. The system of claim 5, wherein the heater is installed adjacent to the focus ring, installed adjacent to a cooling component installed inside the base, or installed adjacent to both the focus ring and the cooling component.

9. The system of claim 1, wherein the dam component is installed when the focus ring is fixed to the base using the fixing component and the sealing component.

10. The system of claim 9, wherein the focus ring is fixed to the base using the fixing component and the sealing component when a gas for controlling a temperature of the focus ring is supplied.

11. The system of claim 1, wherein the sealing component seals a circumference of a side of the fastening component located between the focus ring and the base.

12. The system of claim 8, wherein when the heater is installed adjacent to the focus ring, the heater is installed to contact a bottom part of the focus ring.

13. The system of claim 12, wherein the gas supply unit supplies the gas to the focus ring through the gas supply line, and the gas supply line is formed to penetrate the heater when the heater is installed to contact the entire bottom part of the focus ring and is formed not to penetrate the heater when the heater is installed to partially contact the bottom part of the focus ring.

14. A wafer treatment system comprising:
a housing;
a shower head which is installed on an upper side inside the housing and introduces a process gas for etching a wafer into the housing; and
a support unit which is installed on a lower side inside the housing and comprises an electrostatic chuck on which the wafer is mounted, a base supporting the electrostatic chuck, and a focus ring installed on side surfaces of the electrostatic chuck,
wherein the support unit comprises:
a fixing component which fixes the focus ring to the base;
a sealing component which is disposed between the focus ring and the base to seal a circumference of a fastening component for fastening the fixing component; and
a dam component which is installed outside the sealing component to prevent the sealing component from being etched by the process gas,
wherein the dam component is installed to surround the sealing component when a gas for controlling a temperature of the focus ring is supplied and when the focus ring is fixed to the base using the fixing component and the sealing component.

15. A wafer support unit installed inside a housing that provides a space in which a wafer is treated and comprising:
an electrostatic chuck on which the wafer is mounted;
a base which supports the electrostatic chuck;
a focus ring which is installed on side surfaces of the electrostatic chuck;
a fixing component which fixes the focus ring to the base;
a sealing component which seals a circumference of a fastening component for fastening the focus ring and the base to each other; and
a dam component which is installed outside the sealing component to prevent the sealing component from being etched by a process gas.

16. The wafer support unit of claim 15, wherein the dam component is joined to at least one of the base and the focus ring and then installed outside the sealing component.

17. The wafer support unit of claim 15, further comprising at least one of a heater which is installed inside the base and heats the focus ring and a gas supply unit which supplies a gas for transferring heat generated by the heater to a bottom surface of the focus ring.

18. The wafer support unit of claim 17, wherein the heater is installed adjacent to the focus ring, installed adjacent to a cooling component installed inside the base, or installed adjacent to both the focus ring and the cooling component.

19. The wafer support unit of claim 15, wherein the dam component is installed to surround the sealing component when a gas for controlling a temperature of the focus ring is supplied and when the focus ring is fixed to the base using the fixing component and the sealing component.

20. The wafer support unit of claim 15, wherein the sealing component seals a circumference of a side of the fastening component located between the focus ring and the base.
